(19) United States
(12) Patent Application Publication
(10) Pub. No.: US 2017/0079151 A1
(43) Pub. Date: Mar. 16, 2017

(54) Carrying Case Assembly

(71) Applicant: Wesley Wright, Wayne, PA (US)

(72) Inventor: Wesley Wright, Wayne, PA (US)

(21) Appl. No.: 14/851,801

(22) Filed: Sep. 11, 2015

(51) Int. Cl. H05K 5/02; H04N 5/232; H05K 5/00

(52) U.S. Cl. CPC H05K 5/023; H05K 5/0086; H05K 5/0017; H04N 5/232

(57) ABSTRACT

A carrying case assembly includes a case that may contain an electronic device thereby facilitating the electronic device to record video. A handle is rotatably coupled to the case. The handle may be gripped thereby facilitating the electronic device to be aimed. A control circuit is positioned within the case. The control circuit may be in communication with the electronic device thereby facilitating the control circuit to actuate the electronic device to record the video.

### BACKGROUND OF THE DISCLOSURE

### Field of the Disclosure

The disclosure relates to case devices and more particularly pertains to a new case device for improving stability and control during video recording.

### SUMMARY OF THE DISCLOSURE

An embodiment of the disclosure meets the needs presented above by generally comprising a case that may contain an electronic device thereby facilitating the electronic device to record video. A handle is rotatably coupled to the case. The handle may be gripped thereby facilitating the electronic device to be aimed. A control circuit is positioned within the case. The control circuit may be in communication with the electronic device thereby facilitating the control circuit to actuate the electronic device to record the video.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF THE DRAWINGS

The disclosure will be better understood and objects other than those set forth above will become apparent when consideration is given to the following detailed description thereof. Such description makes reference to the annexed drawings wherein:

FIG. 1 is a top perspective view of a carrying case assembly according to an embodiment of the disclosure.

FIG. 2 is a back view of an embodiment of the disclosure.

FIG. 3 is a back perspective view of an embodiment of the disclosure.

FIG. 4 is a right side view of an embodiment of the disclosure.

FIG. 5 is a front view of an embodiment of the disclosure.

FIG. 6 is a schematic view of an embodiment of the disclosure.

### DESCRIPTION OF THE PREFERRED EMBODIMENT

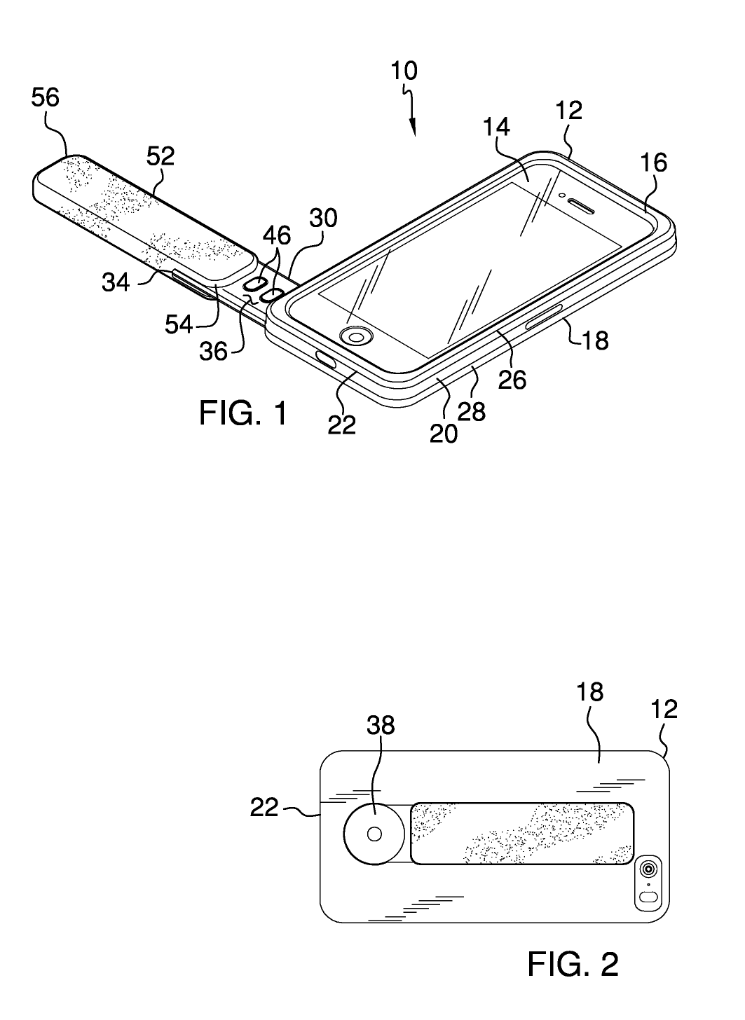

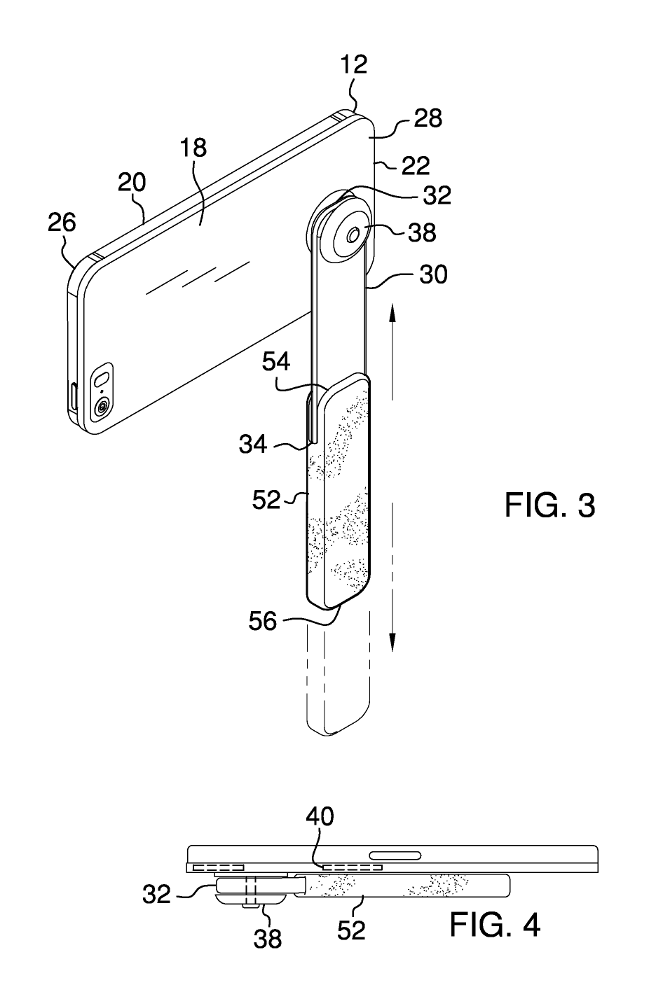

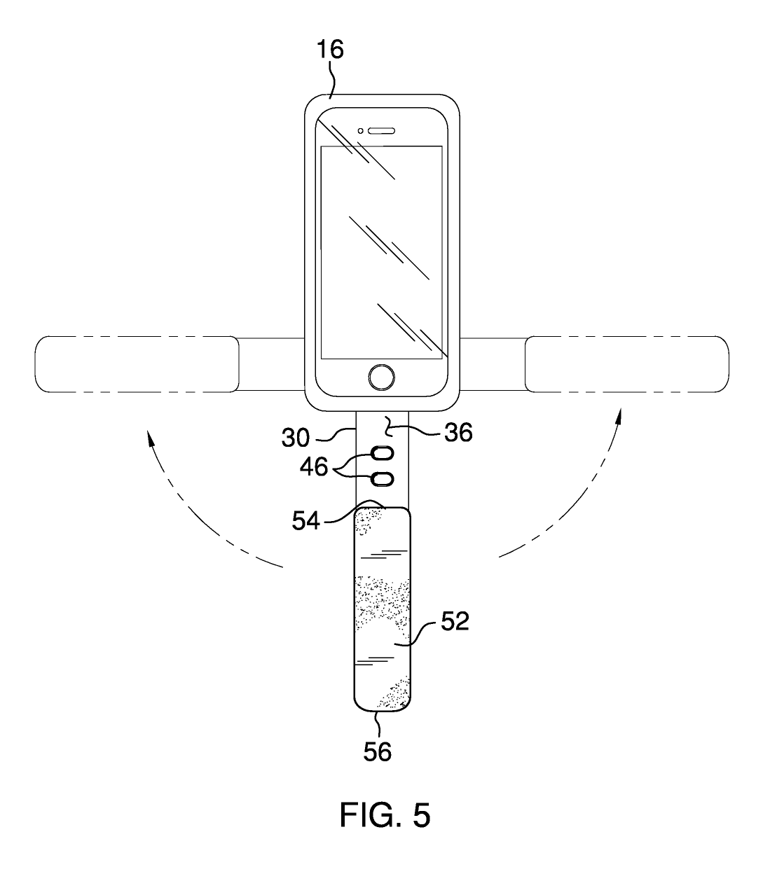

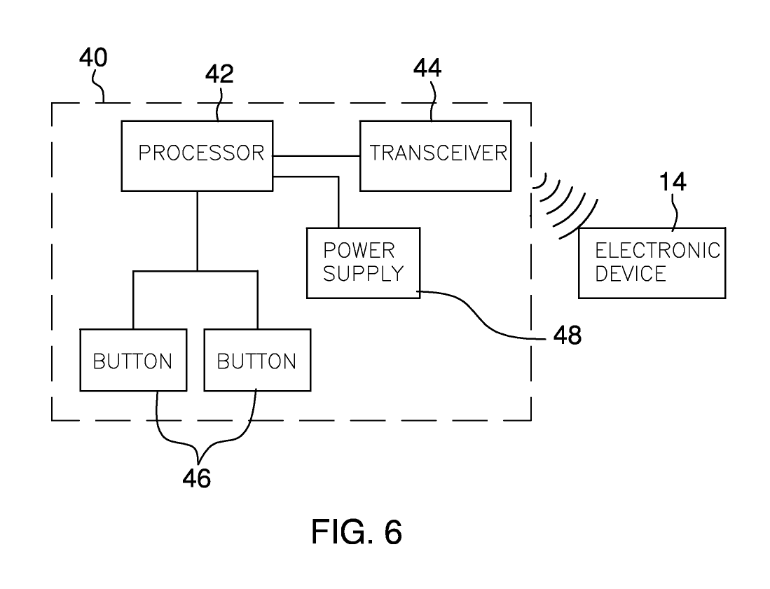

With reference now to the drawings, and in particular to FIGS. 1 through 6 thereof, a new case device embodying the principles and concepts of an embodiment of the disclosure and generally designated by the reference numeral 10 will be described.

As best illustrated in FIGS. 1 through 6, the carrying case assembly 10 generally comprises a case 12 that may contain an electronic device 14 thereby facilitating the electronic device 14 to record video and take photos. The electronic device 14 may comprise a smart phone or the like. The case 12 has a front wall 16, a back wall 18 and a peripheral edge 20 extending between the front wall 16 and the back wall 18. The peripheral edge 20 has a first side 22 and the front wall 16 has an opening 24 extending therethrough. The opening 24 provides access to the electronic device 14 when the electronic device 14 is in the case 12. The peripheral edge 20 is longitudinally split to define a top half 26 of the case that is removably coupled to a bottom half 28 of the case 12.

A handle 30 is rotatably coupled to the case 12 such that the handle 30 may be gripped thereby facilitating the electronic device 14 to be aimed. Additionally, the handle 30 inhibits the electronic device 14 from being dropped or fumbled with during video recording and photo shooting. The handle 30 has a first end 32, a second end 34 and a first surface 36 extending between the first end 32 and the second end 34. The first end 32 is rotatably coupled to the back wall 18 such that the handle 30 is positionable at a selected angle with respect to the peripheral edge 20 case 12.

A pivot 38 extends through the handle 30 and engages the back wall 18 such that the handle 30 is rotatably coupled to the case 12. The pivot 38 is rotatable into a tightening position such that the handle 30 is retained at the selected angle. The pivot 38 is rotatable into a loosening position such that the handle 30 freely pivots on the case 12. The pivot 38 may comprise a screw or the like.

A control circuit 40 is positioned within the case 12. The control circuit 40 is in communication with the electronic device 14 thereby facilitating the control circuit 40 to actuate the electronic device 14 to record the video and take the photo. The control circuit 40 comprises a processor 42 that is positioned within the case 12. The processor 42 may comprise an electronic processor or the like.

A transceiver 44 is positioned within the case 12 and the transceiver 42 is electrically coupled to the processor 42. The transceiver 42 is in electrical communication with the electronic device 14. The transceiver 42 may comprise a radio frequency transceiver that utilizes a WPAN signal. Additionally, the transceiver 42 may utilize Bluetooth technology.

A plurality of buttons 46 is provided and each of the buttons 46 is coupled to the handle 30. Each of the buttons 46 is positioned on the first surface 36 such that each of the buttons 46 may be manipulated. Each of the buttons 46 is electrically coupled to the processor 42. Thus, each of the buttons 46 controls operational parameters of the electronic device 14. A power supply 48 is positioned within the case 12 and the power supply 48 is electrically coupled to the processor 48. The power supply 48 comprises at least one battery 50.

A sleeve 52 is slidably coupled to the handle 30. The sleeve 52 has a first end 54 and a second end 56. The first end 54 of the sleeve 52 is open and the handle 30 extends into the first end 54 of the sleeve 52. The sleeve 52 is positionable in a covering position having the sleeve 52 covering the buttons 46. The sleeve 52 is positionable in an exposing position such that the buttons 46 are exposed. The sleeve 52 enhances a grip of the handle 30 when the sleeve 52 is positioned in the exposing position.

In use, the top half 26 is removed from the bottom half 28 and the electronic device 14 is positioned between the top half 26 and the bottom half 28. The handle 30 is rotated into the selected angle with respect to the case 12 and the pivot 38 is manipulated to retain the handle 30 at the selected angle. The sleeve 52 is positioned in the exposing position and the handle 30 is gripped. The electronic device 14 is pointed in a selected direction and the buttons 46 are manipulated to control video recording and photo taking capabilities of the electronic device 14. The sleeve 52 is positioned in the covering position and the handle 30 is positioned to be coextensive with the back wall 18 of the case 12 when the handle 30 is not in use.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A carrying case assembly configured to aid in video recording, said assembly comprising:
a case being configured to contain an electronic device thereby facilitating the electronic device to record video;
a handle being rotatably coupled to said case wherein said handle is configured to be gripped thereby facilitating the electronic device to be aimed; and
a control circuit being positioned within said case, said control circuit being configured to be in communication with the electronic device thereby facilitating said control circuit to actuate the electronic device to record the video.

2. The assembly according to claim 1, wherein said case has a front wall, a back wall and a peripheral edge extending between said front wall and said back wall, said peripheral edge having a first side, said front wall having an opening extending therethrough wherein said opening is configured to provide access to the electronic device.

3. The assembly according to claim 2, wherein said handle has a first end, a second end and a first surface extending between said first end and said second end, said first end being rotatably coupled to said back wall such that said handle is positionable at a selected angle with respect to said case.

4. The assembly according to claim 3, further comprising a pivot extending through said handle and engaging said back wall such that said handle is rotatably coupled to said case, said pivot being rotatable into a tightening position such that said handle is retained at said selected angle, said pivot being rotatable into a loosening position such that said handle freely pivots on said case.

5. The assembly according to claim 1, wherein said control circuit comprises:
a processor being positioned within said case; and
a transceiver being positioned within said case, said transceiver being electrically coupled to said processor, said transceiver being configured to be in electrical communication with the electronic device.

6. The assembly according to claim 5, further comprising:
said handle having a first surface; and
a plurality of buttons, each of said buttons being coupled to said handle, each of said buttons being positioned on said first surface wherein each of said buttons is configured to be manipulated, each of said buttons being electrically coupled to said processor wherein each of said buttons is configured to control operational parameters of the electronic device.

7. The assembly according to claim 6, further comprising a power supply being positioned within said case, said power supply being electrically coupled to said processor, said power supply comprising at least one battery.

8. The assembly according to claim 1, further comprising a sleeve being slidably coupled to said handle, said sleeve having a first end and a second end, said first end being open, said handle extending into said first end.

9. The assembly according to claim 1, wherein said sleeve is positionable in a covering position having said sleeve covering a plurality of buttons, said sleeve being positionable in an exposing position having said sleeve exposing said buttons, said sleeve being configured to enhance a grip of said handle when said sleeve is positioned in said exposing position.

10. A carrying case assembly configured to aid in video recording, said assembly comprising:
a case being configured to contain an electronic device thereby facilitating the electronic device to record video, said case having a front wall, a back wall and a peripheral edge extending between said front wall and said back wall, said peripheral edge having a first side, said front wall having an opening extending therethrough wherein said opening is configured to provide access to the electronic device;
a handle being rotatably coupled to said case wherein said handle is configured to be gripped thereby facilitating the electronic device to be aimed, said handle having a first end, a second end and a first surface extending between said first end and said second end, said first end being rotatably coupled to said back wall such that said handle is positionable at a selected angle with respect to said case;
a pivot extending through said handle and engaging said back wall such that said handle is rotatably coupled to said case, said pivot being rotatable into a tightening position such that said handle is retained at said selected angle, said pivot being rotatable into a loosening position such that said handle freely pivots on said case;
a control circuit being positioned within said case, said control circuit being configured to be in communication with the electronic device thereby facilitating said control circuit to actuate the electronic device to record the video, said control circuit comprising:
a processor being positioned within said case,
a transceiver being positioned within said case, said transceiver being electrically coupled to said processor, said transceiver being configured to be in electrical communication with the electronic device,
a plurality of buttons, each of said buttons being coupled to said handle, each of said buttons being positioned on said first surface wherein each of said buttons is configured to be manipulated, each of said buttons being electrically coupled to said processor wherein each of said buttons is configured to control operational parameters of the electronic device, and
a power supply being positioned within said case, said power supply being electrically coupled to said processor, said power supply comprising at least one battery; and
a sleeve being slidably coupled to said handle, said sleeve having a first end and a second end, said first end of said sleeve being open, said handle extending into said first end of said sleeve, said sleeve being positionable in a covering position having said sleeve covering said buttons, said sleeve being positionable in an exposing position having said sleeve exposing said buttons, said sleeve being configured to enhance a grip of said handle when said sleeve is positioned in said exposing position.
